(19) United States
(12) Patent Application Publication
(10) Pub. No.: US 2026/0262337 A1
(43) Pub. Date: Sep. 3, 2026

(54) LIGHT-EMITTING SUBSTRATE AND MANUFACTURING METHOD THEREFOR, AND DISPLAY APPARATUS

(71) Applicants: Beijing BOE Technology Development Co., Ltd., Beijing (CN); BOE Technology Group Co., Ltd., Beijing (CN)

(72) Inventors: Can WANG, Beijing (CN); Can ZHANG, Beijing (CN); Jinfei NIU, Beijing (CN); Ning CONG, Beijing (CN); Jingjing ZHANG, Beijing (CN); Jiakui YAN, Beijing (CN)

(21) Appl. No.: 19/474,383

(22) PCT Filed: Apr. 16, 2024
(86) PCT No.: PCT/CN2024/088114

§ 371 Date: Oct. 10, 2025

(30) Foreign Application Priority Data
May 26, 2023 (CN) 202310611299.3

(51) Int. Cl. H10H 20/815; H10H 20/812; H10H 29/01; H10H 29/14; H10H 29/80; H10H 29/85

(52) U.S. Cl. CPC H10H 20/815; H10H 20/812; H10H 29/011; H10H 29/032; H10H 29/0364; H10H 29/142; H10H 29/8321; H10H 29/8323; H10H 29/857

(57) ABSTRACT

Disclosed in the embodiments of the present disclosure are a light-emitting substrate and a manufacturing method therefor, and a display apparatus. The space between N-type semiconductor layers of adjacent first light-emitting chips is filled with a barrier structure, such that the barrier structure can damage a PNP structure formed when the N-type semiconductor layers are shared originally, and leakage currents between adjacent light-emitting chips can be greatly reduced, thereby avoiding the problem of light-emission crosstalk between adjacent pixels. In addition, in the present disclosure, a transparent conductive layer is arranged on the side of each N-type semiconductor layer that faces away from a driving backboard, such that all the N-type semiconductor layers can be electrically-<connected together by means of the transparent conductive layer, and the design of all first light-emitting chips sharing the N-type semiconductor layers can be ensured.

### CROSS-REFERENCE TO RELATED APPLICATIONS

The present application is a National Stage of International Application No. PCT/CN2024/088114, filed Apr. 16, 2024, which claims the priority for Chinese patent application No. 202310611299.3 filed with China National Intellectual Property Administration on May 26, 2023, all contents of which are incorporated by reference herein.

### TECHNICAL FIELD

The present disclosure relates to the field of display technology, and in particular to a light-emitting substrate, a manufacturing method therefor, and a display device.

### BACKGROUND

With the development of optoelectronic display technology and semiconductor manufacturing technology, OLED (organic light-emitting diode) and LCD (liquid crystal display) display technologies have been mass-used, and Micro LED (micrometer light-emitting diode) display technology is also under development. Micro LED display technology is considered to be the best display technology of the future due to its high stability, long life, better display effect, and higher resolution.

### SUMMARY

The embodiments of the present disclosure provide a light-emitting substrate, a manufacturing method therefor, and a display device, which are used to avoid the problem of light crosstalk between light-emitting chips adjacent to each other.

The present disclosure provides a light-emitting substrate, including: a driving backplane; a plurality of first light-emitting chips, arranged in an array on the driving backplane, where the first light-emitting chip includes a P-type semiconductor layer, a multi-quantum well layer, and an N-type semiconductor layer sequentially stacked on the driving backplane, the P-type semiconductor layer is electrically connected to the driving backplane, and a barrier structure is filled between the N-type semiconductor layers of the first light-emitting chips adjacent to each other; and a transparent conductive layer, located on a side of the N-type semiconductor layer facing away from the driving backplane.

Optionally, in the above-mentioned light-emitting substrate provided in the embodiment of the present disclosure, an orthographic projection of the barrier structure on the driving backplane does not overlap with an orthographic projection of the P-type semiconductor layer on the driving backplane.

Optionally, in the above-mentioned light-emitting substrate provided in the embodiment of the present disclosure, the barrier structure is provided with a grid structure, and the N-type semiconductor layers are located in meshes of the grid structure.

Optionally, in the above-mentioned light-emitting substrate provided in the embodiment of the present disclosure, a thickness of the barrier structure is the same as a thickness of the N-type semiconductor layer.

Optionally, in the above-mentioned light-emitting substrate provided in the embodiment of the present disclosure, a material of the barrier structure is a conductive material or a non-conductive material.

Optionally, the above-mentioned light-emitting substrate provided in the embodiment of the present disclosure, further includes: a plurality of array electrodes, located between the driving backplane and the plurality of first light-emitting chips, where the plurality of array electrodes are electrically connected to the driving backplane; and a plurality of P-terminal pads, respectively located between the plurality of array electrodes and the plurality of first light-emitting chips, where the plurality of P-terminal pads are electrically connected to the P-type semiconductor layers and the plurality of array electrodes.

Optionally, the above-mentioned light-emitting substrate provided in the embodiment of the present disclosure, further includes: a connecting electrode, located on the driving backplane and electrically connected to the driving backplane, where the connecting electrode is disposed at a periphery of the plurality of array electrodes, and an orthographic projection of the N-type semiconductor layer close to the connecting electrode on the driving backplane covers an orthographic projection of the connecting electrode on the driving backplane; and an N-terminal pad, located between the connecting electrode and the N-type semiconductor layer, where the N-terminal pad is electrically connected to the N-type semiconductor layer and the connecting electrode.

Optionally, the above-mentioned light-emitting substrate provided in the embodiment of the present disclosure, further includes: a common electrode ring, disposed around the plurality of array electrodes, where the common electrode ring is electrically connected to the transparent conductive layer.

Optionally, the above-mentioned light-emitting substrate provided in the embodiment of the present disclosure, further includes: an insulating filling layer, filled between the plurality of P-terminal pads and the P-type semiconductor layer, and filled between first light-emitting chips adjacent to each other; and an insulating protection layer, located between the plurality of array electrodes and plurality of the P-terminal pads, where the plurality of P-terminal pads are electrically connected to the plurality of array electrodes through via holes penetrating through the insulating protection layer.

Optionally, the above-mentioned light-emitting substrate provided in the embodiment of the present disclosure, further includes: a P-electrode layer, located between the plurality of P-terminal pads and the P-type semiconductor layer, and electrically connected to the plurality of P-terminal pads.

Optionally, the above-mentioned light-emitting substrate provided in the embodiment of the present disclosure, further includes: a plurality of second light-emitting chips, located between the plurality of first light-emitting chips and the P-electrode layer; and an electrical connection layer, located between the plurality of first light-emitting chips and the plurality of second light-emitting chips.

Optionally, the above-mentioned light-emitting substrate provided in the embodiment of the present disclosure, further includes: a metal electrode layer, located between the N-type semiconductor layers of the plurality of first light-emitting chips and the transparent conductive layer.

Optionally, in the above-mentioned light-emitting substrate provided in the embodiment of the present disclosure, the P-type semiconductor layers of the plurality of first light-emitting chips are independently arranged; and the multi-quantum well layers of the plurality of first light-emitting chips are independently arranged, or the multi-quantum well layers of the plurality of first light-emitting chips are an integrated structure; and the P-type semiconductor layers of the plurality of second light-emitting chips are independently arranged, the multi-quantum well layers of the plurality of second light-emitting chips are independently arranged, and the N-type semiconductor layers of the plurality of second light-emitting chips are independently arranged.

Accordingly, an embodiment of the present disclosure further provides a display device, including the above-mentioned light-emitting substrate provided by the embodiment of the present disclosure.

Accordingly, an embodiment of the present disclosure further provides a method for manufacturing a light-emitting substrate, including: preparing a driving backplane; sequentially forming a buffer semiconductor layer and an N-type semiconductor thin film, that are stacked and disposed in an entire surface, on a base substrate; forming multi-quantum well layers on the N-type semiconductor thin film disposed in the entire surface; forming a plurality of P-type semiconductor layers patterned on the multi-quantum well layers; bonding the base substrate with the P-type semiconductor layers formed thereon to the driving backplane, wherein the P-type semiconductor layers are electrically connected to the driving backplane; removing the base substrate and the buffer semiconductor layer; patterning the N-type semiconductor thin film disposed in the entire surface to form a plurality of N-type semiconductor layers corresponding to the plurality of P-type semiconductor layers; wherein the P-type semiconductor layer, the multi-quantum well layer, and the N-type semiconductor layer constitute a first light-emitting chip; filling a barrier structure in a gap of the N-type semiconductor layers adjacent to each other; and forming a transparent conductive layer on the N-type semiconductor layers and the barrier structure.

### BRIEF DESCRIPTION OF FIGURES

FIG. 1 is a schematic structural diagram of a Micro-LED chip fabricated on a sapphire substrate.

FIG. 2 is a schematic structural diagram for performing an I-V test on a light-emitting chip in FIG. 1.

FIG. 3 is I-V data obtained by testing the single light-emitting chip in FIG. 2.

FIG. 4 is I-V test data between light-emitting chips adjacent to each other in FIG. 2.

FIG. 5 is a schematic diagram of a PNP structure formed between light-emitting chips adjacent to each other in FIG. 2.

FIG. 6 is a schematic structural diagram of a light-emitting substrate provided in an embodiment of the present disclosure.

FIG. 7 is another schematic structural diagram of a light-emitting substrate provided in an embodiment of the present disclosure.

FIG. 8 is a schematic plan view of an N-type semiconductor layer 203 and a barrier structure 30 in FIG. 6 and FIG. 7.

FIG. 9 is another schematic structural diagram of a light-emitting substrate provided in an embodiment of the present disclosure.

FIG. 10 is a schematic flow chart of a method for manufacturing a light-emitting substrate provided in an embodiment of the present disclosure.

FIGS. 11A to 11K are schematic structural diagrams of the light-emitting substrate shown in FIG. 6 after each step is performed in the manufacturing process according to an embodiment of the present disclosure.

FIGS. 12A-12L are schematic structural diagrams of the light-emitting substrate shown in FIG. 7 after each step is performed in the manufacturing process according to an embodiment of the present disclosure.

FIG. 13 is a schematic structural diagram of a display device provided in an embodiment of the present disclosure.

### DETAILED DESCRIPTION

In order to make the purpose, technical solution and advantages of the present disclosure clearer, the present disclosure will be further described in detail below in conjunction with the accompanying drawings. Obviously, the described embodiments are only part of the embodiments of the present disclosure, rather than all the embodiments. Based on the embodiments in the present disclosure, all other embodiments obtained by ordinary technicians in the field without creative work are within the claimed scope of the present disclosure.

The thickness and shape of each film layer in the drawings do not reflect the actual proportion of the light-emitting substrate, and the purpose is only to illustrate the contents of the present disclosure.

As an inorganic light-emitting device, LED can be used at a brightness of millions (or even higher), which can meet the needs of use in more extreme environments. Micro-LED display technology refers to a new type of display technology realized by using Micro-LED chips. Micro-LED display has outstanding characteristics such as high brightness, long life, wide color gamut, and good stability. It can meet the personalized needs of high-end display, such as new applications such as ultra-high-definition display, AR glasses, medical display, and vehicle-mounted display.

Currently, Micro-LED display technology for AR applications is still in the early stages of commercialization, but it is expected to become the main technology for future micro-displays. AR applications usually require 5000 or higher PPI (pixel resolution), which means that the pixel pitch should be less than 5 microns. Such a small pixel size requires special processing of the pixels, such as the pixel island solution, or the monochrome screen direct bonding solution.

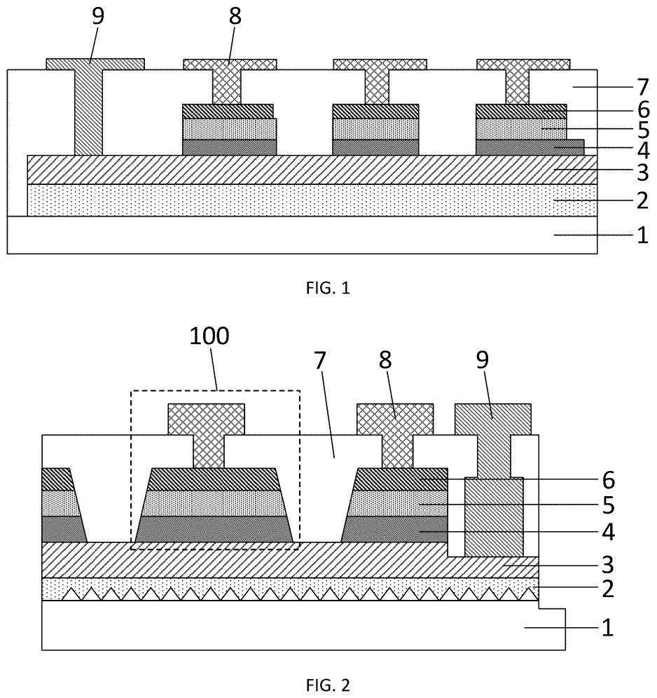

The production of Micro LED light-emitting substrates requires transferring as many as millions to tens of millions of Micro LED chips from the growth substrate (sapphire substrate) to the driving backplane. As shown in FIG. 1, FIG. 1 is a schematic structural diagram of Micro-LED chips made on a sapphire substrate. The Micro-LED chip includes: a sapphire substrate 1, a buffer semiconductor layer 2 on the sapphire substrate 1, an N-type semiconductor layer 3 on the buffer semiconductor layer 2, a plurality of multi-quantum well layers 4 on the N-type semiconductor layer 3, a P-type semiconductor layer 5 on the multi-quantum well layer 4, a transparent electrode layer 6 on the P-type semiconductor layer 5, an insulating layer 7 arranged on the transparent electrode layer 6, P-terminal pads 8 on the insulating layer 7 and electrically connected one-to-one with the transparent electrode layer 6, and N-terminal pads 9 electrically connected to the N-type semiconductor layer 3. Each region of the multi-quantum well layer 4 corresponds to a sub-pixel, and all sub-pixels share the N-type semiconductor layer 3.

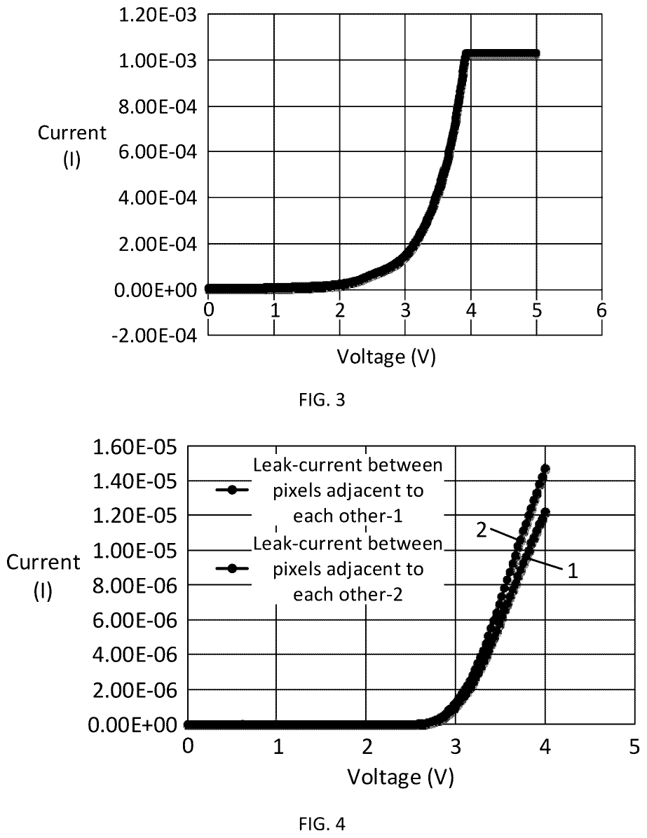

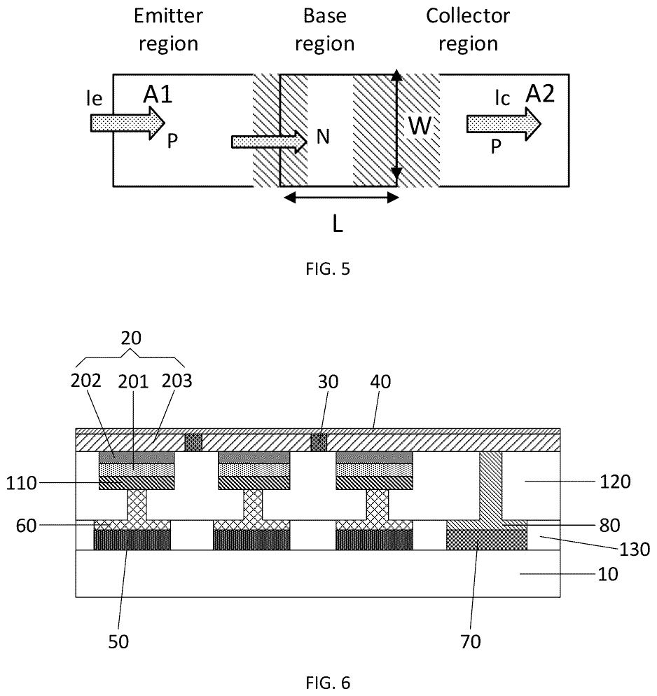

The pixel island solution and the monochrome screen direct bonding solution mentioned above both adopt the structure of the shared N-type semiconductor layer 3 shown in FIG. 1. The inventor of the present disclosure found that the structure of the shared N-type semiconductor layer 3 shown in FIG. 1 has the risk of light crosstalk between pixels adjacent to each other. As shown in FIG. 2, FIG. 2 is a schematic structural diagram of an I-V test of a light-emitting chip 100 in FIG. 1, where a voltage of 0 to 5V is applied to the P-terminal pad 8 of the light-emitting chip 100, and a voltage of OV is applied to the N-terminal pad 9. The measured I-V data of a single light-emitting chip is shown in FIG. 3, and the current of a single chip is on the order of 10E⁻³ A. The I-V test data between light-emitting chips adjacent to each other is shown in FIG. 4, and the leakage current between light-emitting chips adjacent to each other can reach 10E⁻⁵ A, and this level of leakage current can cause light emission. The inventor of the present disclosure analyzed the principle of leakage current, as shown in FIG. 5, which is a simplified diagram of a PNP structure formed between light-emitting chips adjacent to each other. The PNP structure is similar to a triode structure, where Ie is the current from the P region to the N region (arrow A1) (normal light-emitting current), and Ic is the current from the N region to the P region (arrow A2) (leakage current). The formula of Ic is as follows:

$${I}_{n C} = \frac{{A}_{E q {D}_{n}} {n}_{p 0}}{{L}_{n}} coth ( \frac{w}{{L}_{n}} ) exp ( \frac{{qV}_{BE}}{k T} ) .$$

If Ic is required to be equal to 0, there needs to be no connection between the emitter region and the collector region, that is, the transistor effect disappears, and the width W of the N-type semiconductor layer needs to tend to ∞, or the ratio of the width W of the N-type semiconductor layer to the length L of the N-type semiconductor layer, W/L>>1, but in the actual manufacturing process, these two methods are unrealistic.

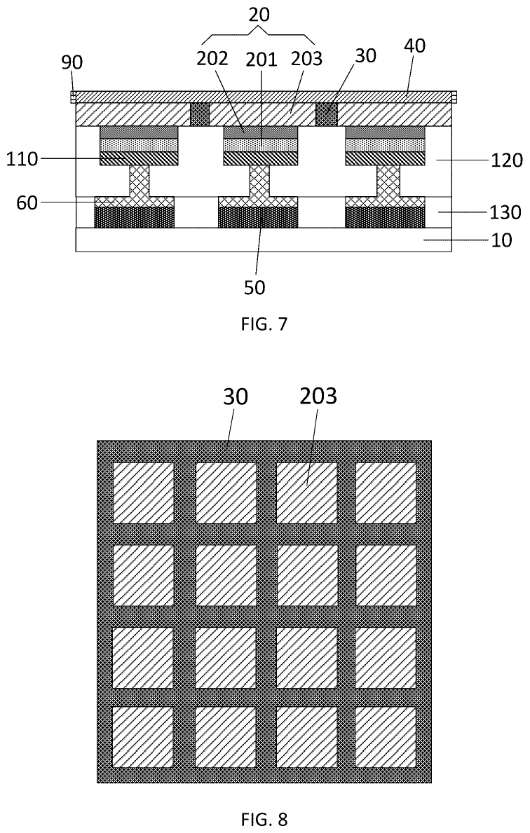

Therefore, in order to solve the problem of light crosstalk between pixels adjacent to each other of a Micro LED light-emitting substrate, an embodiment of the present disclosure provides a light-emitting substrate, as shown in FIG. 6 and FIG. 7, including: a driving backplane 10; a plurality of first light-emitting chips 20, arranged in an array on the driving backplane 10, and a transparent conductive layer 40, located on a side of the N-type semiconductor layer 203 facing away from the driving backplane 10. The first light-emitting chip 20 includes a P-type semiconductor layer 201, a multi-quantum well layer 202, and an N-type semiconductor layer 203 which are sequentially stacked on the driving backplane 10. The P-type semiconductor layer 201 is electrically connected to the driving backplane 10. A barrier structure 30 is filled between the N-type semiconductor layers 203 of first light-emitting chips 20 adjacent to each other.

The above-mentioned light-emitting substrate provided by the embodiment of the present disclosure is provided with the barrier structure filled between the N-type semiconductor layers of first light-emitting chips adjacent to each other. Such a barrier structure can destroy the PNP structure originally formed when the N-type semiconductor layer is shared, and can greatly reduce the leakage current between light-emitting chips adjacent to each other, thereby avoiding the problem of light-emitting crosstalk between pixels adjacent to each other. Additionally, the present disclosure provides the transparent conductive layer on the side of the N-type semiconductor layer facing away from the driving backplane, and the transparent conductive layer can electrically connect the N-type semiconductor layers together, thereby ensuring the design that all the first light-emitting chips share the N-type semiconductor layer.

In a specific implementation, the material of the transparent conductive layer can be indium tin oxide (ITO) material, indium zinc oxide (IZO) material, metal alloy material (eg, Ag/Mg), metal nanowire (eg, Ag nanowire), metal grid, or graphene, etc.

The N-type semiconductor layer refers to an impurity semiconductor layer in which the free electron concentration is much greater than the hole concentration, and the P-type semiconductor layer is also called a hole-type semiconductor layer, which is a semiconductor layer that mainly conducts electricity through positively charged holes.

Optionally, the N-type semiconductor layer may be formed of N-type doped gallium nitride (N—GaN), and the P-type semiconductor layer may be formed of P-type doped gallium nitride (P—GaN).

In a specific implementation, in the above-mentioned light-emitting substrate provided in the embodiment of the present disclosure, as shown in FIG. 6 and FIG. 7, the orthographic projection of the barrier structure 30 on the driving backplane 10 does not overlap with the orthographic projection of the P-type semiconductor layer 201 on the driving backplane 10. In this way, the barrier structure 30 does not affect the normal light emission of the first light-emitting chip 20.

Optionally, as shown in FIGS. 6 and 7, the width of the barrier structure 30 may be smaller than the distance between the P-type semiconductor layers 201 of first light-emitting chips 20 adjacent to each other. Of course, the width of the barrier structure 30 may also be equal to the distance between the P-type semiconductor layers 201 of first light-emitting chips 20 adjacent to each other.

In a specific implementation, in the above-mentioned light-emitting substrate provided in the embodiment of the present disclosure, as shown in FIG. 8, FIG. 8 is a schematic plan view of the N-type semiconductor layer 203 and the barrier structure 30 in FIGS. 6 and 7. The barrier structure 30 is provided with a grid structure, and the N-type semiconductor layers 203 are located in meshes of the grid structure. In this way, the barrier structure 30 separates the N-type semiconductor layers 203 of the first light-emitting chips 20 from each other, and destroys the PNP structure between first light-emitting chips 20 adjacent to each other on the surface, thereby avoiding the light crosstalk problem between pixels adjacent to each other.

In specific implementation, in the above-mentioned light-emitting substrate provided in the embodiment of the present disclosure, as shown in FIGS. 6 and 7, the material of the barrier structure 30 can be a conductive material or a non-conductive material. Optionally, the conductive material can be a metal, and the non-conductive material can be an organic insulating layer or an inorganic insulating layer.

In a specific implementation, in the above-mentioned light-emitting substrate provided in the embodiment of the present disclosure, as shown in FIGS. 6 and 7, the thickness of the barrier structure 30 can be the same as the thickness of the N-type semiconductor layer. Of course, the thickness of the barrier structure 30 can be greater than the thickness of the N-type semiconductor layer. For example, when the material of the barrier structure 30 is a conductive material, the thickness of the barrier structure 30 can be set to be greater than the thickness of the N-type semiconductor layer, so that the resistance of the N-type semiconductor layer 203 can be reduced and the light-emitting efficiency can be improved.

Optionally, the barrier structure 30 may be provided with a thickness in a range of 0.5 μm to 3 μm.

In a specific implementation, the above-mentioned light-emitting substrate provided in the embodiment of the present disclosure, as shown in FIG. 6 and FIG. 7 further includes: a plurality of array electrodes 50, disposed between the driving backplane 10 and the first light-emitting chips 20, where the array electrodes 50 are electrically connected to the driving backplane 10; and a plurality of P-terminal pads 60 each, disposed between the array electrode 50 and the corresponding first light-emitting chip 20, where the P-terminal pad 60 is electrically connected to the P-type semiconductor layer 201 and the array electrodes 50. In this way, the first light-emitting chips 20 formed on the sapphire substrate can be transferred to the driving backplane 10, and the P-terminal pads 60 can be bonded to the array electrodes 50 by a reflow soldering process.

In a specific implementation, the above-mentioned light-emitting substrate provided in the embodiment of the present disclosure, as shown in FIG. 6 further includes: a connecting electrode 70, disposed on the driving backplane 10 and electrically connected to the driving backplane 10. The connecting electrode 70 is disposed on the periphery of the plurality of array electrodes 50, and the orthographic projection of the N-type semiconductor layer 203 close to the connecting electrode 70 on the driving backplane 10 covers the orthographic projection of the connecting electrode 70 on the driving backplane 10.

The N-terminal pad 80 is disposed between the connecting electrode 70 and the N-type semiconductor layer 203, and the N-terminal pad 80 is electrically connected to the N-type semiconductor layer 203 and the connecting electrode 70. In this way, the first light-emitting chip 20 formed on the sapphire substrate can be transferred to the driving backplane 10, and the N-terminal pad 80 can be bonded to the connecting electrode 70 by a reflow soldering process.

In a specific implementation, in the above-mentioned light-emitting substrate provided in the embodiment of the present disclosure, as shown in FIG. 6, the driving backplane 10 provides a common voltage to the N-type semiconductor layer 203 through the connecting electrode 70, and provides a driving voltage to the first light-emitting chip 20 corresponding to the array electrode 50 through different array electrodes 50, thereby lighting up the first light-emitting chip 20 electrically connected to the array electrode 50.

It should be noted that the first light-emitting chip 20 shown in FIG. 6 is a flip-chip structure.

In a specific implementation, the above-mentioned light-emitting substrate provided in the embodiment of the present disclosure, as shown in FIG. 7 further includes: a common electrode ring 90, disposed around the plurality of array electrodes 50 and electrically connected to the transparent conductive layer 40. The common electrode ring 90 can be disposed in the same layer as the transparent conductive layer 40 and is used to provide a common voltage for the transparent conductive layer 40.

In a specific implementation, in the above-mentioned light-emitting substrate provided in the embodiment of the present disclosure, as shown in FIG. 7, a common voltage is provided to the N-type semiconductor layer 203 through the common electrode ring 90, and a driving voltage is provided to the first light-emitting chip 20 corresponding to the array electrode 50 through different array electrodes 50, thereby lighting up the first light-emitting chip 20 electrically connected to the array electrode 50.

It should be noted that the first light-emitting chip 20 shown in FIG. 7 is a vertical structure.

Optionally, in the embodiment of the present disclosure, the driving backplane 10 may drive the first light-emitting chips 20 to emit light in an active manner or a passive manner.

In specific implementation, the above-mentioned light-emitting substrate provided in the embodiment of the present disclosure, as shown in FIG. 6 and FIG. 7 further includes: a P-electrode layer 110, located between the P-terminal pads 60 and the P-type semiconductor layer 201 and electrically connected to the P-terminal pads 60. Optionally, the material of the P-electrode layer 110 can be a reflective metal. Since part of the light emitted by the first light-emitting chips 20 during operation will be irradiated from one side of the P-type semiconductor layer 201 to the driving backplane 10, the P-electrode layer 110 made of a reflective metal and arranged between the P-terminal pads 60 and the P-type semiconductor layer 201 can reflect the light emitted from the first light-emitting chips 20 and irradiated from the P-type semiconductor layer 201 toward the drive backplane 10) back along its original path, so that the light emitted by the first light-emitting chips 20 can be completely irradiated out along the direction from one side of the driving backplane 10 to the P-type semiconductor layer 201, thereby improving the luminous efficiency of the first light-emitting chips 20.

Of course, the material of the P-electrode layer 110 can also be a metal/ITO stacked structure, so that on the basis of improving the luminous efficiency of the first light-emitting chips 20, the work function of the P-type semiconductor layer 201 can be reduced, thereby improving the conductivity of the P-type semiconductor layer 201.

Of course, the material of the P-electrode layer 110 may also be ITO, so that the P-electrode layer 110 can reduce the work function of the P-type semiconductor layer 201, but does not have reflective properties. Those skilled in the art can select the material of the P-electrode layer 110 as needed.

In a specific implementation, the above-mentioned light-emitting substrate provided in the embodiment of the present disclosure, as shown in FIG. 6 and FIG. 7 further includes: an insulating filling layer 120, filled between the P-terminal pads 60 and the P-type semiconductor layer 201, and between first light-emitting chips 20 adjacent to each other, where the insulating filling layer 120 can separate first light-emitting chips 20 adjacent to each other; and an insulating protection layer 130, located between the array electrodes 50 and the P-terminal pads 60. The P-terminal pad 60 is electrically connected to the array electrode 50 through a via hole penetrating the insulating protection layer 130. The insulating protection layer 130 serves to protect the array electrodes 50.

In a specific implementation, the material of the insulating filling layer 120 and the material of the insulating protection layer 130 can both be inorganic materials, such as silicon nitride, silicon oxide, silicon oxynitride, and the like.

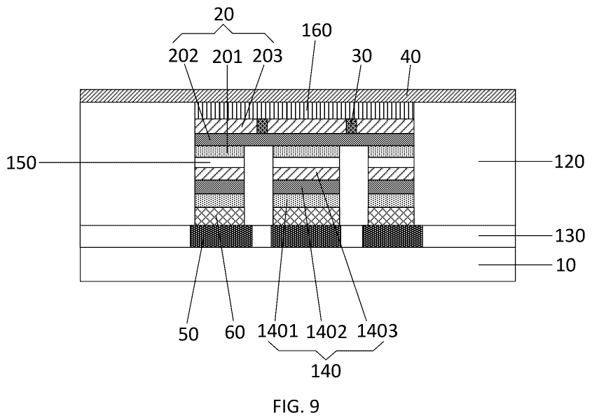

In a specific implementation, the above-mentioned light-emitting substrate provided in the embodiment of the present disclosure, as shown in FIG. 9 further includes: a plurality of second light-emitting chips 140, respectively disposed between the first light-emitting chips 20 and the P-electrode layer 110; and an electrical connection layer 150, located between the first light-emitting chips 20 and the second light-emitting chips 140. Thus, by arranging two light-emitting chips in the vertical direction, the light-emitting efficiency can be further improved.

In specific implementation, in the above-mentioned light-emitting substrate provided in the embodiment of the present disclosure, as shown in FIG. 9, the material of the electrical connection layer 150 may be a transparent conductive material, such as ITO, IZO, etc. The transparent conductive material does not affect the light-emitting direction of the light-emitting chip.

In a specific implementation, the above-mentioned light-emitting substrate provided in the embodiment of the present disclosure, as shown in FIG. 9 further includes: a metal electrode layer 160, located between the N-type semiconductor layer 203 and the transparent conductive layer 40 of the first light-emitting chips 20. This can further reduce the resistance of the N-type semiconductor layer 203, which is beneficial to further improve the light-emitting efficiency.

In a specific implementation, in the above-mentioned light-emitting substrate provided in the embodiment of the present disclosure, as shown in FIG. 6, FIG. 7 and FIG. 9, the P-type semiconductor layers 201 of the first light-emitting chips 20 are independently arranged; the multi-quantum well layers 202 of the first light-emitting chips 20 are independently arranged, or the multi-quantum well layers 202 of the first light-emitting chips 20 are an integrated structure. The integrated structure can simplify the manufacturing process of the multi-quantum well layer 202. FIG. 6 and FIG. 7 take the multi-quantum well layers 202 of the first light-emitting chips 20 being independently arranged as an example, and FIG. 9 takes the multi-quantum well layers 202 of the first light-emitting chips 20 being an integrated structure as an example.

The P-type semiconductor layers 1401 of the second light-emitting chips 140 are independently arranged, the multi-quantum well layers 1402 of the second light-emitting chips 140 are independently arranged, and the N-type semiconductor layers 1403 of the second light-emitting chips 140 are independently arranged. In this way, it can be ensured that pixels adjacent to each other emit light independently.

It should be noted that the structure of the light-emitting chip shown in FIG. 9 can be the flip-chip structure shown in FIG. 6, so in FIG. 9, the N-terminal pad 80 electrically connected to the N-type semiconductor layer 203 needs to be provided and the connecting electrode 70 electrically connected to the N-terminal pad 80 is provided on the driving backplane 10. The structure of the light-emitting chip shown in FIG. 9 can also be the vertical structure shown in FIG. 7, so the common electrode ring 90 electrically connected to the transparent conductive layer 40 needs to be provided.

In a specific implementation, in the above-mentioned light-emitting substrate provided in the embodiment of the present disclosure, the size of the first light-emitting chip and the size of the second light-emitting chip are generally less than 200 μm. For example, the first light-emitting chip and the second light-emitting chip may be Micro LEDs. Since the size of Micro LED is small, the pixel resolution of the light-emitting substrate can be improved. The size of Micro LED is generally less than 100 μm. Of course, the first light-emitting chip and the second light-emitting chip may also be other light-emitting chips such as Mini LEDs, which is not limited in the present disclosure. When the first light-emitting chip and the second light-emitting chip are Mini LEDs, the size of Mini LED ranges from 100 μm to 200 μm.

In specific implementation, the above-mentioned light-emitting substrate provided in the embodiment of the present disclosure may also include other functional film layers well known to those skilled in the art, which will not be described in detail here.

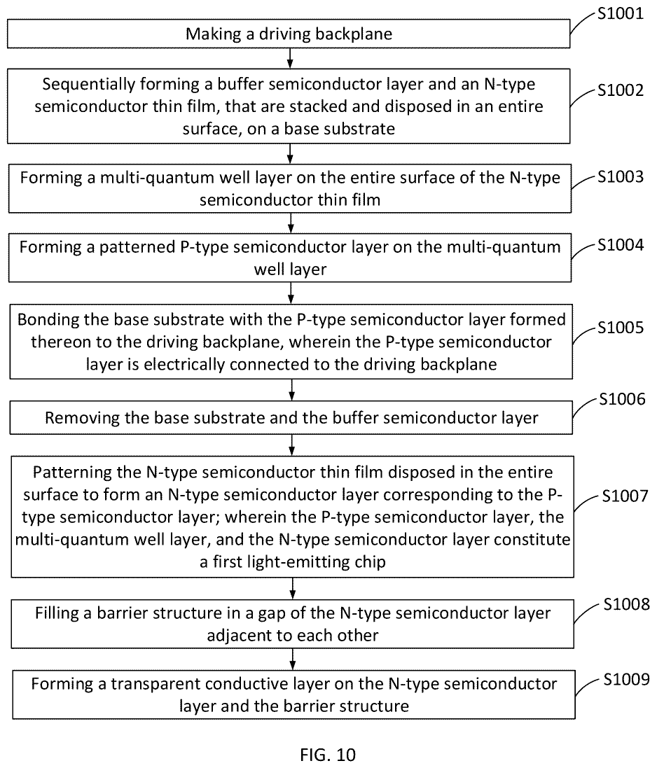

Based on the same inventive concept, the embodiment of the present disclosure also provides a method for manufacturing a light-emitting substrate, as shown in FIG. 10, including the following steps.
S1001, a driving backplane is made.
S1002, a buffer semiconductor layer and an N-type semiconductor thin film which are stacked and disposed in an entire surface are sequentially forming on a base substrate.
S1003, a multi-quantum well layer is formed on the entire surface of the N-type semiconductor thin film.
S1004, a patterned P-type semiconductor layer is formed on the multi-quantum well layer.
S1005, the base substrate with the P-type semiconductor layer formed thereon is bonded to the driving backplane, where the P-type semiconductor layer is electrically connected to the driving backplane.
S1006, the base substrate and the buffer semiconductor layer are removed.
S1007, the N-type semiconductor thin film disposed in the entire surface is patterned to form an N-type semiconductor layer corresponding to the P-type semiconductor layer. The P-type semiconductor layer, the multi-quantum well layer, and the N-type semiconductor layer constitute a first light-emitting chip.
S1008, a barrier structure is filled in a gap between the N-type semiconductor layers adjacent to each other.
S1009, a transparent conductive layer is formed on the N-type semiconductor layer and the barrier structure.

The manufacturing method of the above-mentioned light-emitting substrate provided by the embodiment of the present disclosure is to fill the barrier structure between the N-type semiconductor layers of first light-emitting chips adjacent to each other. Such a barrier structure can destroy the PNP structure originally formed when the N-type semiconductor layer is shared, and can greatly reduce the leakage current between light-emitting chips adjacent to each other, thereby avoiding the problem of light-emitting crosstalk between pixels adjacent to each other. Additionally, the present disclosure provides the transparent conductive layer on the side of the N-type semiconductor layer facing away from the driving backplane, and the transparent conductive layer can electrically connect the N-type semiconductor layers together, thereby ensuring the design that all the first light-emitting chips share the N-type semiconductor layers.

The following describes the manufacturing methods of the light-emitting substrates shown in FIG. 6 and FIG. 7, respectively.

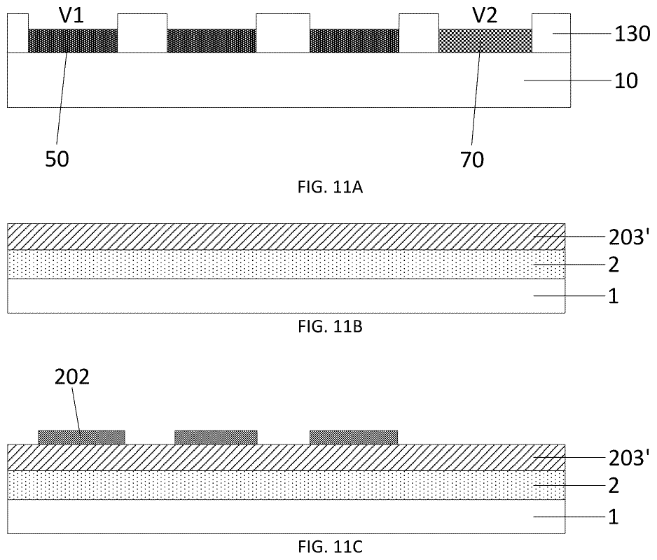

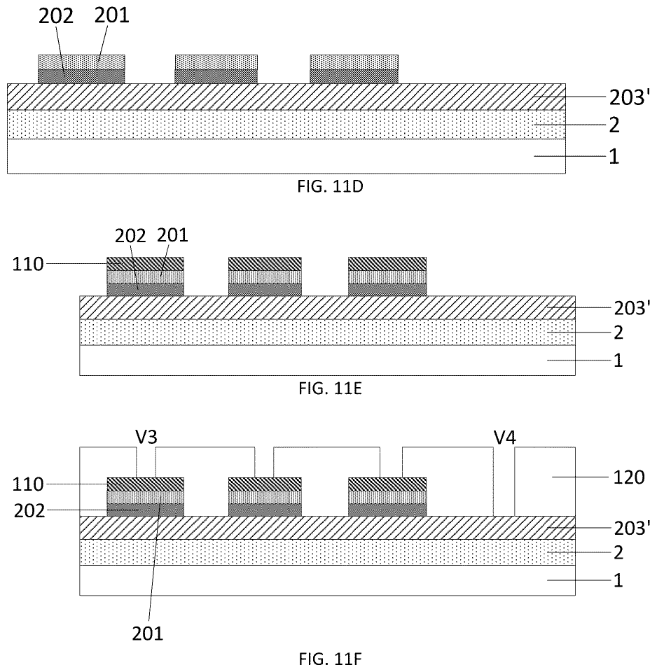

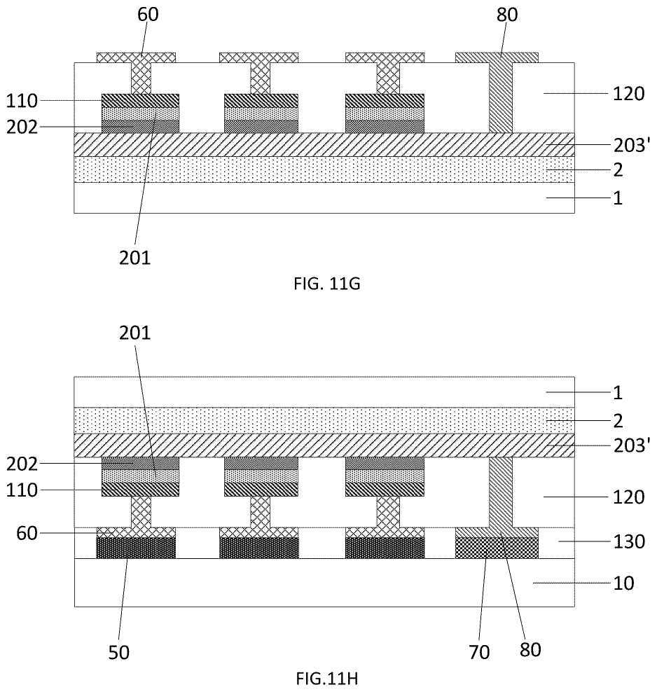

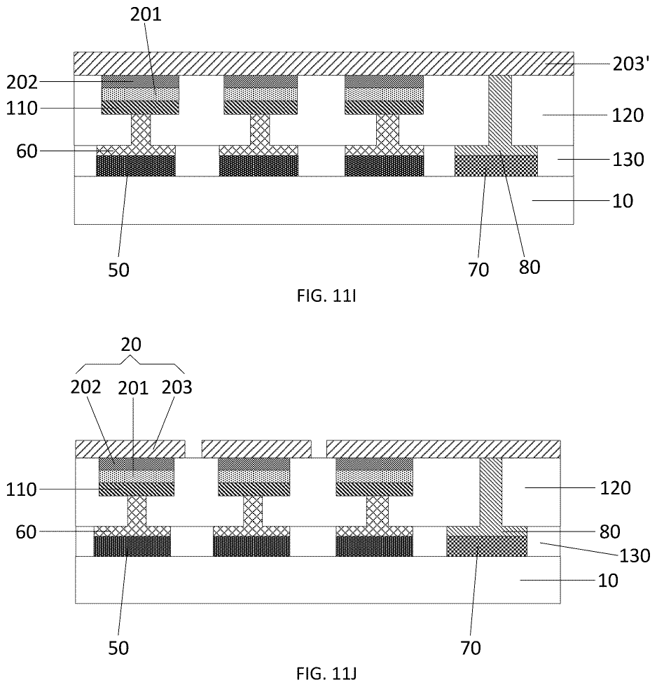

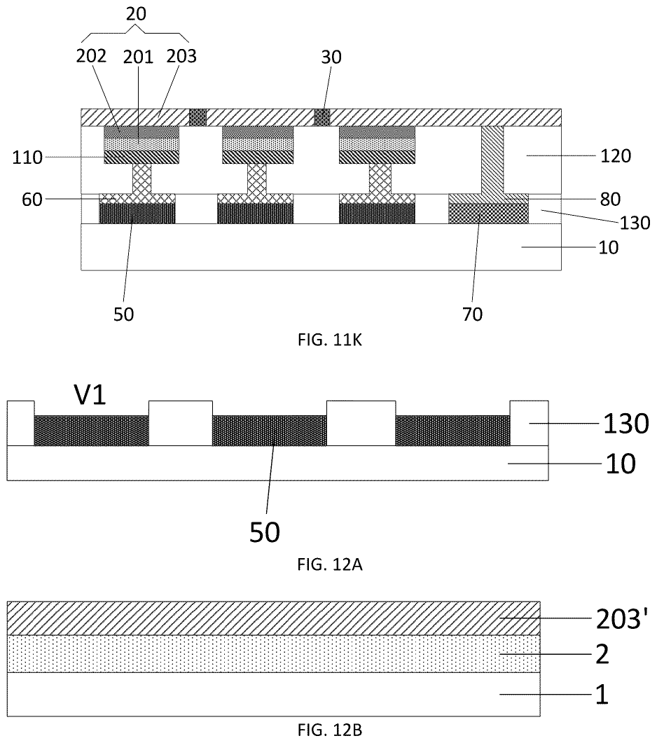

The steps for making the light-emitting substrate shown in FIG. 6 are as follows.
(1) A driving backplane 10 is manufactured, a plurality of array electrodes 50 and connecting electrode 70 located a periphery of the array electrodes 50 are formed on the driving backplane 10, and an insulating protection layer 130 is formed on the plurality of array electrodes 50. The insulating protection layer 130 is provided with via holes V1 at positions corresponding to the array electrodes 50 to expose the array electrodes 50, and is provided with a first opening V2 at a position corresponding to the connecting electrode 70, as shown in FIG. 11A.
(2) A buffer semiconductor layer 2 and an N-type semiconductor thin film 203′ are sequentially formed on a base substrate (e.g., a sapphire substrate 1) in a stacked manner and arranged in the entire surface, as shown in FIG. 11B.
(3) A patterned multi-quantum well layer 202 is formed on the entire surface of the N-type semiconductor thin film 203′, as shown in FIG. 11C.
(4) A p patterned P-type semiconductor layer 201 is formed on the multi-quantum well layer 202, as shown in FIG. 11D.
(5) A P-electrode layer 110 is formed on the P-type semiconductor layer 201 in one-to-one correspondence therewith, as shown in FIG. 11E.
(6) An insulating filling layer 120 is formed on the P-electrode layer 110, and second openings V3 are formed in the insulating filling layer 120 at positions of the insulating filling layer corresponding to the P-electrode layer 110, and a third opening V4 is formed in the insulating filling layer 120 at the periphery of the P-electrode layer 110, as shown in FIG. 11F.
(7) P-terminal pads 60 corresponding to the P-electrode layer 110 are formed on the insulating filling layer 120, and an N-terminal pad 80 is formed on the periphery of the P-terminal pads 60. The P-terminal pads 60 are electrically connected to the P-electrode layer 110 through the second openings V3, and the N-terminal pad 80 is electrically connected to the N-type semiconductor thin film 203′ through the third opening V4, as shown in FIG. 11G.
(8) The base substrate 1 with the P-terminal pads 60 is bonded to the driving backplane 10. The P-terminal pads 60 are electrically connected one-to-one with the array electrodes 50, and the N-terminal pad 80 is electrically connected to the connecting electrode 70, as shown in FIG. 11H.
(9) The base substrate 1 and the buffer semiconductor layer 2 are removed by a laser lift-off process, as shown in FIG. 11I.
(10) The entire surface of the N-type semiconductor thin film 203′ is patterned to form the N-type semiconductor layer 203 corresponding to the P-type semiconductor layer 201; where the P-type semiconductor layer 201, the multi-quantum well layer 202 and the N-type semiconductor layer 203 constitute the first light-emitting chip 20, as shown in FIG. 11J.
(11) A barrier structure 30 is filled in the gap of the N-type semiconductor layer 203, as shown in FIG. 11K.
(12) A transparent conductive layer 40 is formed on the N-type semiconductor layer 203 and the barrier structure 30, as shown in FIG. 6.

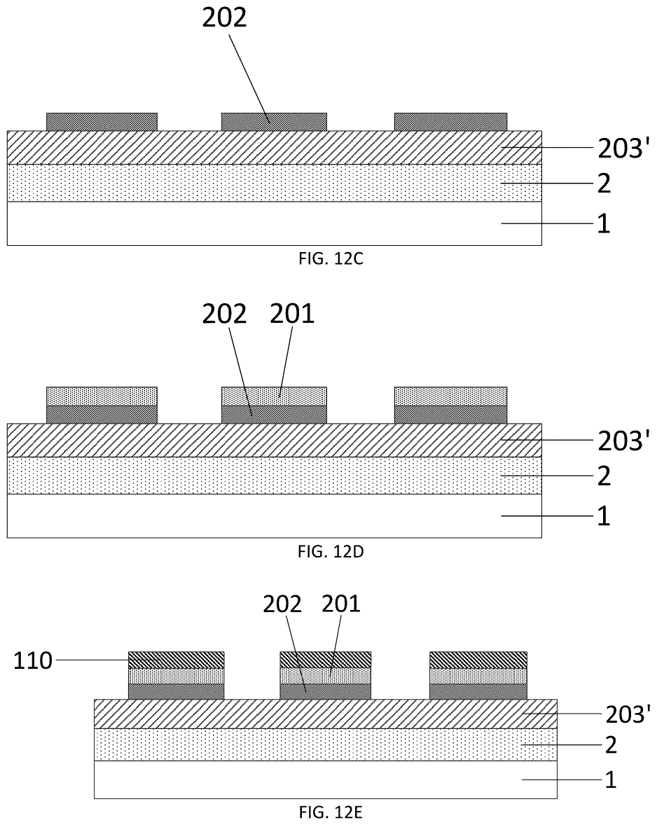

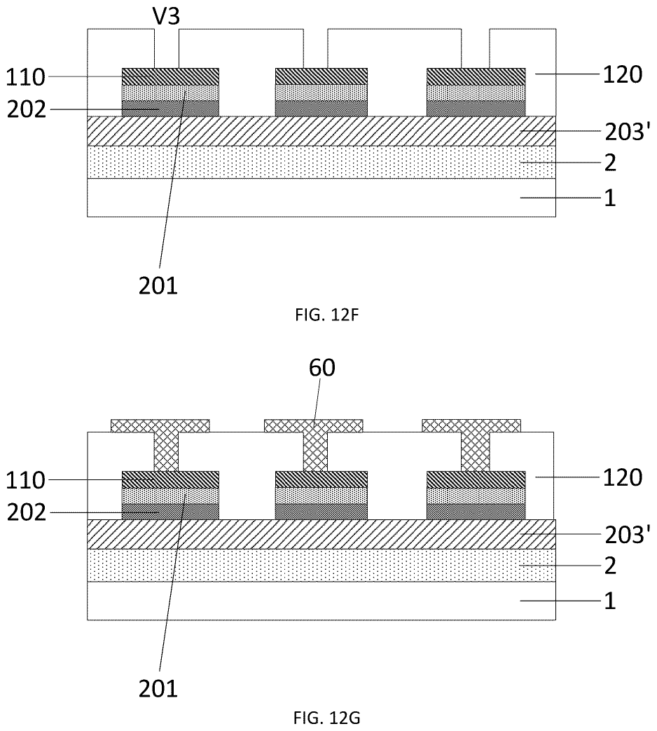

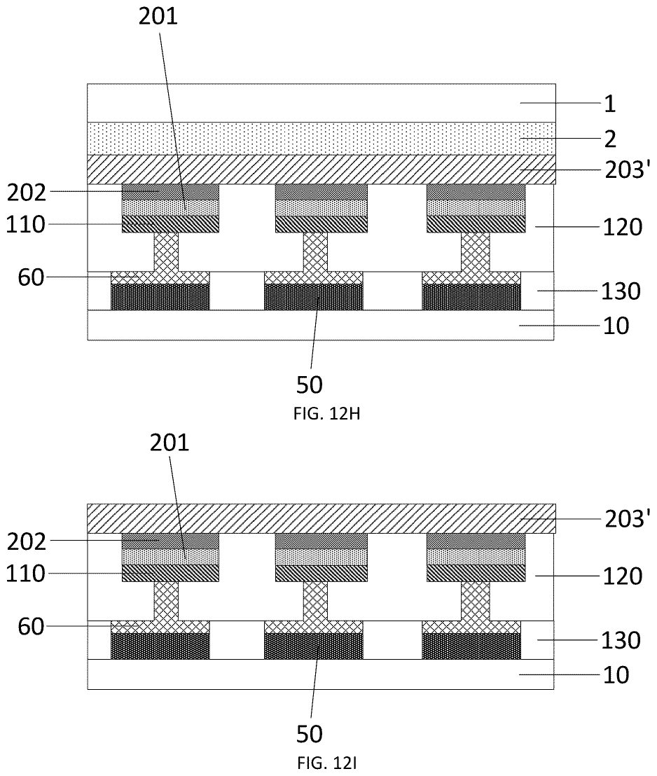

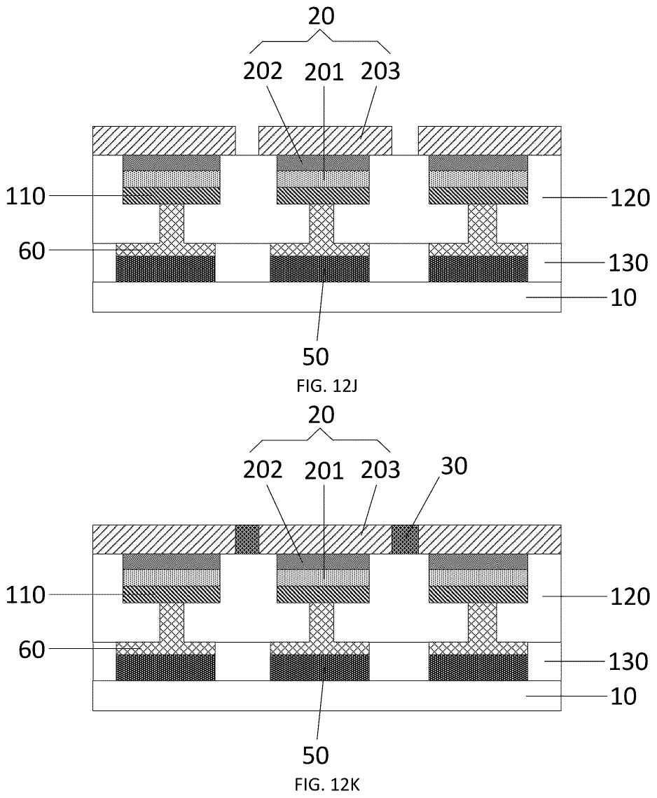

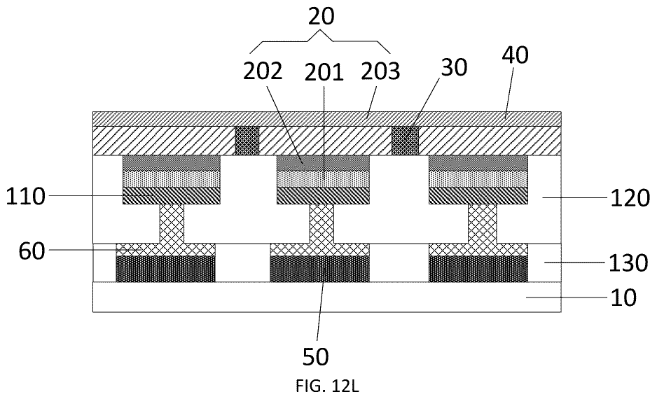

The steps for making the light-emitting substrate shown in FIG. 7 are as follows.
(1) A driving backplane 10 is manufactured, a plurality of array electrodes 50 are formed on the driving backplane 10, and an insulating protection layer 130 is formed on the plurality of array electrodes 50. The insulating protection layer 130 is provided with via holes V1 at positions corresponding to the array electrodes 50 to expose the array electrodes 50, as shown in FIG. 12A.
(2) A buffer semiconductor layer 2 and an N-type semiconductor thin film 203′ are sequentially formed on a base substrate (e.g., a sapphire substrate 1) in a stacked manner and arranged in the entire surface, as shown in FIG. 12B.
(3) A patterned multi-quantum well layer 202 is formed on the entire surface of the N-type semiconductor thin film 203′, as shown in FIG. 12C.
(4) A patterned P-type semiconductor layer 201 is formed on the multi-quantum well layer 202, as shown in FIG. 12D.
(5) A P-electrode layer 110 is formed on the P-type semiconductor layer 201 in one-to-one correspondence therewith, as shown in FIG. 12E.
(6) An insulating filling layer 120 is formed on the P-electrode layer 110, and second openings V3 are formed in the insulating filling layer 120 at positions of the insulating filling layer corresponding to the P-electrode layer 110, as shown in FIG. 12F.
(7) P-terminal pads 60 corresponding to the P-electrode layer 110 are formed on the insulating filling layer 120, as shown in FIG. 12G.
(8) The base substrate 1 with the P-terminal pads 60 is bonded to the driving backplane 10, and the P-terminal pads 60 are electrically connected one-to-one with the array electrodes 50, as shown in FIG. 12H.
(9) The base substrate 1 and the buffer semiconductor layer 2 are removed by a laser lift-off process, as shown in FIG. 12I.
(10) The entire surface of the N-type semiconductor thin film 203′ is patterned to form the N-type semiconductor layer 203 corresponding to the P-type semiconductor layer 201; where the P-type semiconductor layer 201, the multi-quantum well layer 202 and the N-type semiconductor layer 203 constitute the first light-emitting chip 20, as shown in FIG. 12J.
(11) A barrier structure 30 is filled in the gap of the N-type semiconductor layer 203, as shown in FIG. 12K.
(12) A transparent conductive layer 40 is formed on the N-type semiconductor layer 203 and the barrier structure 30, as shown in FIG. 12L.
(13) A common electrode ring 90 electrically connected to the transparent conductive layer 40 is formed on the periphery of the transparent conductive layer 40, as shown in FIG. 7.

In specific implementation, the above-mentioned manufacturing method provided in the embodiment of the present disclosure also includes manufacturing other functional film layers well known to those skilled in the art, which will not be described in detail here.

Based on the same inventive concept, the embodiment of the present disclosure also provides a display device, including the above-mentioned light-emitting substrate provided by the embodiments of the present disclosure. The principle of solving the problem by the display device is similar to that of the above-mentioned light-emitting substrate, so the implementation of the display device can refer to the implementation of the above-mentioned light-emitting substrate, and the repeated parts will not be repeated here.

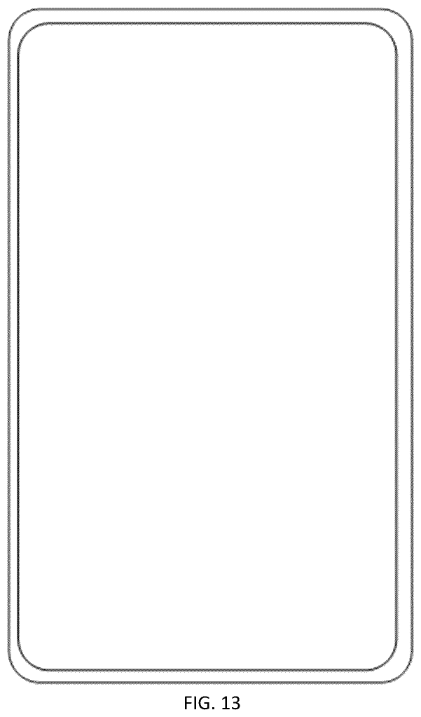

In specific implementation, the display device provided in the embodiment of the present disclosure may be a full-screen mobile phone as shown in FIG. 13. Of course, the display device provided in the embodiment of the present disclosure may also be any product or component with a display function, such as a tablet computer, a television, a display, a laptop computer, a digital photo frame, a navigator, etc. Other essential components of the display device are understood by ordinary technicians in the field, and will not be elaborated here, nor should they be used as limitations of the present disclosure.

The embodiments of the present disclosure provide the light-emitting substrate, the manufacturing method therefor, and the display device. The barrier structure is filled between the N-type semiconductor layers of first light-emitting chips adjacent to each other. Such a barrier structure can destroy the PNP structure originally formed when the N-type semiconductor layer is shared, and can greatly reduce the leakage current between light-emitting chips adjacent to each other, thereby avoiding the problem of light-emitting crosstalk between pixels adjacent to each other. Additionally, the present disclosure provides the transparent conductive layer on the side of the N-type semiconductor layer facing away from the driving backplane, and the transparent conductive layer can electrically connect the N-type semiconductor layers together, thereby ensuring the design that all the first light-emitting chips share the N-type semiconductor layers.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalents, the present disclosure is also intended to include these modifications and variations.

1. A light-emitting substrate, comprising:
a driving backplane;
a plurality of first light-emitting chips, arranged in an array on the driving backplane, wherein the first light-emitting chip comprises a P-type semiconductor layer, a multi-quantum well layer, and an N-type semiconductor layer sequentially stacked on the driving backplane, the P-type semiconductor layer is electrically connected to the driving backplane, and a barrier structure is filled between the N-type semiconductor layers of the first light-emitting chips adjacent to each other; and
a transparent conductive layer, located on a side of the N-type semiconductor layer facing away from the driving backplane.

2. The light-emitting substrate according to claim 1, wherein an orthographic projection of the barrier structure on the driving backplane does not overlap with an orthographic projection of the P-type semiconductor layer on the driving backplane.

3. The light-emitting substrate according to claim 1, wherein the barrier structure is provided with a grid structure, and the N-type semiconductor layers are located in meshes of the grid structure.

4. The light-emitting substrate according to claim 1, wherein a thickness of the barrier structure is the same as a thickness of the N-type semiconductor layer.

5. The light-emitting substrate according to claim 1, wherein a material of the barrier structure is a conductive material or a non-conductive material.

6. The light-emitting substrate according to claim 1, further comprising:
a plurality of array electrodes, located between the driving backplane and the plurality of first light-emitting chips, wherein the plurality of array electrodes are electrically connected to the driving backplane; and
a plurality of P-terminal pads, respectively located between the plurality of array electrodes and the plurality of first light-emitting chips, wherein the plurality of P-terminal pads are electrically connected to the P-type semiconductor layers and the plurality of array electrodes.

7. The light-emitting substrate according to claim 6, further comprising:
a connecting electrode, located on the driving backplane and electrically connected to the driving backplane, wherein the connecting electrode is disposed at a periphery of the plurality of array electrodes, and an orthographic projection of the N-type semiconductor layer close to the connecting electrode on the driving backplane covers an orthographic projection of the connecting electrode on the driving backplane; and
an N-terminal pad, located between the connecting electrode and the N-type semiconductor layer, wherein the N-terminal pad is electrically connected to the N-type semiconductor layer and the connecting electrode.

8. The light-emitting substrate according to claim 6, further comprising:
a common electrode ring, disposed around the plurality of array electrodes, wherein the common electrode ring is electrically connected to the transparent conductive layer.

9. The light-emitting substrate according to claim 6, further comprising:
an insulating filling layer, filled between the plurality of P-terminal pads and the P-type semiconductor layer, and filled between first light-emitting chips adjacent to each other; and
an insulating protection layer, located between the plurality of array electrodes and plurality of the P-terminal pads, wherein the plurality of P-terminal pads are electrically connected to the plurality of array electrodes through via holes penetrating through the insulating protection layer.

10. The light-emitting substrate according to claim 6, further comprising:
a P-electrode layer, located between the plurality of P-terminal pads and the P-type semiconductor layer, and electrically connected to the plurality of P-terminal pads.

11. The light-emitting substrate according to claim 10, further comprising:
a plurality of second light-emitting chips, located between the plurality of first light-emitting chips and the P-electrode layer; and
an electrical connection layer, located between the plurality of first light-emitting chips and the plurality of second light-emitting chips.

12. The light-emitting substrate according to claim 11, further comprising:
a metal electrode layer, located between the N-type semiconductor layers of the plurality of first light-emitting chips and the transparent conductive layer.

13. The light-emitting substrate according to claim 11, wherein the P-type semiconductor layers of the plurality of first light-emitting chips are independently arranged; and the multi-quantum well layers of the plurality of first light-emitting chips are independently arranged, or the multi-quantum well layers of the plurality of first light-emitting chips are an integrated structure; and
the P-type semiconductor layers of the plurality of second light-emitting chips are independently arranged, the multi-quantum well layers of the plurality of second light-emitting chips are independently arranged, and the N-type semiconductor layers of the plurality of second light-emitting chips are independently arranged.

14. A display device, comprising: the light-emitting substrate according to claim 1.

15. A method for manufacturing a light-emitting substrate, comprising:
preparing a driving backplane;
sequentially forming a buffer semiconductor layer and an N-type semiconductor thin film, that are stacked and disposed in an entire surface, on a base substrate;
forming multi-quantum well layers on the N-type semiconductor thin film disposed in the entire surface;
forming a plurality of P-type semiconductor layers patterned on the multi-quantum well layers;
bonding the base substrate with the P-type semiconductor layers formed thereon to the driving backplane, wherein the P-type semiconductor layers are electrically connected to the driving backplane;
removing the base substrate and the buffer semiconductor layer;
patterning the N-type semiconductor thin film disposed in the entire surface to form a plurality of N-type semiconductor layers corresponding to the plurality of P-type semiconductor layers; wherein the P-type semiconductor layer, the multi-quantum well layer, and the N-type semiconductor layer constitute a first light-emitting chip;
filling a barrier structure in a gap of the N-type semiconductor layers adjacent to each other; and
forming a transparent conductive layer on the N-type semiconductor layers and the barrier structure.

16. The light-emitting substrate according to claim 2, further comprising:
a plurality of array electrodes, located between the driving backplane and the plurality of first light-emitting chips, wherein the plurality of array electrodes are electrically connected to the driving backplane; and
a plurality of P-terminal pads, respectively located between the plurality of array electrodes and the plurality of first light-emitting chips, wherein the plurality of P-terminal pads are electrically connected to the P-type semiconductor layers and the plurality of array electrodes.

17. The light-emitting substrate according to claim 3, further comprising:
a plurality of array electrodes, located between the driving backplane and the plurality of first light-emitting chips, wherein the plurality of array electrodes are electrically connected to the driving backplane; and
a plurality of P-terminal pads, respectively located between the plurality of array electrodes and the plurality of first light-emitting chips, wherein the plurality of P-terminal pads are electrically connected to the P-type semiconductor layers and the plurality of array electrodes.

18. The light-emitting substrate according to claim 4, further comprising:
a plurality of array electrodes, located between the driving backplane and the plurality of first light-emitting chips, wherein the plurality of array electrodes are electrically connected to the driving backplane; and
a plurality of P-terminal pads, respectively located between the plurality of array electrodes and the plurality of first light-emitting chips, wherein the plurality of P-terminal pads are electrically connected to the P-type semiconductor layers and the plurality of array electrodes.

19. The light-emitting substrate according to claim 7, further comprising:
an insulating filling layer, filled between the plurality of P-terminal pads and the P-type semiconductor layer, and filled between first light-emitting chips adjacent to each other; and
an insulating protection layer, located between the plurality of array electrodes and plurality of the P-terminal pads, wherein the plurality of P-terminal pads are electrically connected to the plurality of array electrodes through via holes penetrating through the insulating protection layer.

20. The light-emitting substrate according to claim 8, further comprising:
an insulating filling layer, filled between the plurality of P-terminal pads and the P-type semiconductor layer, and filled between first light-emitting chips adjacent to each other; and
an insulating protection layer, located between the plurality of array electrodes and plurality of the P-terminal pads, wherein the plurality of P-terminal pads are electrically connected to the plurality of array electrodes through via holes penetrating through the insulating protection layer.
